(19) United States
(12) Patent Application Publication
(10) Pub. No.: US 2022/0223531 A1
(43) Pub. Date: Jul. 14, 2022

(54) SEMICONDUCTOR MODULE AND MANUFACTURING METHOD THEREFOR

(71) Applicant: ULTRAMEMORY INC., Tokyo (JP)

(72) Inventors: Takatoshi MASUDA, Tokyo (JP); Fumitake OKUTSU, Tokyo (JP)

(21) Appl. No.: 17/615,047

(22) PCT Filed: May 31, 2019
(86) PCT No.: PCT/JP2019/021810

§ 371 Date: Nov. 29, 2021

(51) Int. Cl. H01L 23/538; H01L 25/065; H01L 21/48; H01L 25/00

(52) U.S. Cl. CPC H01L 23/5384; H01L 25/0657; H01L 24/16; H01L 25/50; H01L 21/486

(57) ABSTRACT

A semiconductor module that can absorb thermal stress, and a manufacturing method therefor are provided. A semiconductor module includes a film interposer that includes a plurality of through electrodes which run in the thickness direction; a logic chip that is disposed on one surface side of the film interposer, and is connected electrically to the through electrodes; and a RAM unit that is a RAM module disposed on the other surface side of the film interposer, and connected electrically to the logic chip via the through electrodes.

### TECHNICAL FIELD

The present disclosure relates to a semiconductor module and a method of manufacturing the same.

### BACKGROUND ART

Conventionally, volatile memory (RAM) such as DRAM (Dynamic Random Access Memory) has been known as a storage device. In DRAM, high-performance arithmetic units (hereinafter referred to as logical chips) and large-capacity capable of withstanding an increase in the amount of data are required. Therefore, a reduction in the size of memory devices (memory cell arrays and memory chips) and increase in capacity owing to planar expansion of cells have been attempted. However, due to the weakness to noise caused by the reduction in size and the increase in die area, for example, such an increase in capacity has reached a limit.

Recently, a technique has been developed in which a plurality of planar memory devices are stacked and three-dimensionalized (3D) to realize large-capacity memory. In addition, there has been proposed a semiconductor module in which a plurality of chips are arranged in an overlapping manner to reduce the footprint of a plurality of chips (for example, refer to Patent Document 1).
Patent Document 1: Japanese Unexamined Patent Application, Publication No. 2015-216169

### DISCLOSURE OF THE DISCLOSURE

### Problems to be Solved by the Disclosure

According to Patent Document 1, by arranging two chips in an overlapping manner, the distance between the two chips can be shortened. This can be expected to improve the bandwidth between the two chips. On the other hand, when heat stress is applied to the semiconductor module, due to the generation of thermal stress, cracks in the solder bumps may occur. In addition, warpage of the chip may occur due to the heat.

Exemplary embodiments of the present disclosure provide a semiconductor module that makes it possible to absorb thermal stress and a manufacturing method thereof.

### Means for Solving the Problems

An exemplary embodiment of the present disclosure is directed to a semiconductor module including: a film interposer including a plurality of through electrodes penetrating in a thickness direction; a logical chip provided on one face of the film interposer, and electrically connected to the plurality of through electrodes; and a RAM unit serving as a RAM module provided on one other face of the film interposer, and electrically connected to the logical chip via the plurality of through electrodes.

Furthermore, it is preferable that at least a portion of the logical chip and at least a portion of the RAM unit are provided to overlap each other with the film interposer interposed therebetween.

Furthermore, it is preferable that the semiconductor module further includes a substrate that is provided on the other face of the film interposer and holds the RAM unit between the substrate and the other face of the film interposer.

Furthermore, it is preferable that the substrate includes a recess portion at a position overlapping with the RAM unit to include the RAM unit therein.

Furthermore, it is preferable that the film interposer includes a base film, and a plurality of vias penetrating the base film.

Furthermore, an exemplary embodiment of the present disclosure is directed to a manufacturing method of a semiconductor module, including the steps of: forming a plurality of through electrodes in a film interposer; providing a plate-shaped support so as to face one face of the film interposer; providing a RAM unit on one other face of the film interposer; providing a substrate on the other face of the film interposer so as to hold the RAM unit between the substrate and the film interposer; removing the support; and providing a logical chip on the one face of the film interposer.

Furthermore, an exemplary embodiment of the present disclosure is directed to a manufacturing method of a semiconductor module, including the steps of: forming a plurality of through electrodes in a film interposer; providing a plate-shaped frame so as to face an end of one face of the film interposer; providing a RAM unit on one other face of the film interposer; providing a substrate on the other face of the film interposer so as to hold the RAM unit between the substrate and the film interposer; removing the frame; and providing a logical chip on the one face of the film interposer.

### Effects of the Disclosure

According to exemplary embodiments of the present disclosure, it is possible to provide a semiconductor module that makes it possible to absorb thermal stress, and a manufacturing method thereof.

### BRIEF DESCRIPTION OF THE DRAWINGS

FIG. 1 is a schematic perspective view showing a semiconductor module according to a first exemplary embodiment of the present disclosure.

FIG. 2 is a schematic cross-sectional view showing a semiconductor module of the first embodiment.

FIG. 3 shows a schematic cross-sectional view showing a process of manufacturing the semiconductor module of the first embodiment.

FIG. 4 shows a schematic cross-sectional view showing a process of manufacturing the semiconductor module of the first embodiment.

FIG. 5 shows a schematic cross-sectional view showing a process of manufacturing the semiconductor module of the first embodiment.

FIG. 6 shows a schematic cross-sectional view showing a process of manufacturing the semiconductor module of the first embodiment.

FIG. 7 shows a schematic cross-sectional view showing a process of manufacturing the semiconductor module of the first embodiment.

FIG. 8 shows a schematic cross-sectional view showing a process of manufacturing the semiconductor module of the first embodiment.

FIG. 9 shows a schematic cross-sectional view showing a process of manufacturing the semiconductor module of the first embodiment.

FIG. 10 is a schematic cross-sectional view showing a process of manufacturing a semiconductor module according to a second exemplary embodiment of the present disclosure.

FIG. 11 shows a schematic cross-sectional view showing a process of manufacturing the semiconductor module of the second embodiment.

FIG. 12 shows a schematic cross-sectional view showing a process of manufacturing the semiconductor module of the second embodiment.

FIG. 13 is a schematic cross-sectional view showing a semiconductor module according to a third exemplary embodiment of the present disclosure.

FIG. 14 is a schematic cross-sectional view showing a semiconductor module according to a fourth exemplary embodiment of the present disclosure.

FIG. 15 is a schematic cross-sectional view showing a semiconductor module according to a fifth exemplary embodiment of the present disclosure.

FIG. 16 is a schematic cross-sectional view showing a semiconductor module according to a sixth exemplary embodiment of the present disclosure.

### PREFERRED MODE FOR CARRYING OUT THE DISCLOSURE

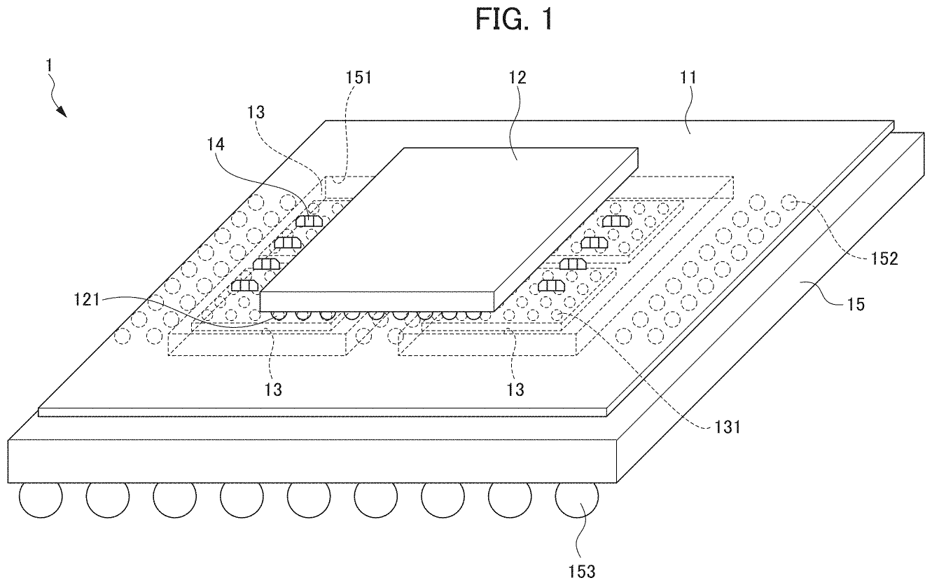

Hereinafter, a semiconductor module 1 according to each exemplary embodiment of the present disclosure and a manufacturing method thereof will be described with reference to FIGS. 1 to 16. The semiconductor module 1 according to each exemplary embodiment is, for example, an SIP (system in a package) in which an arithmetic unit 12 (hereinafter, referred to as a logical chip) and a RAM unit 13, which is a RAM module including a single-layer or stacked RAM, are provided on a substrate 15. The semiconductor module 1 is provided on another substrate (such as a motherboard, not shown), and electrically connected thereto using solder balls 153 (power source balls, etc.). It is possible for the semiconductor module 1 to obtain power from another substrate, and transmit and receive data between the other substrates. It should be noted that, in the following exemplary embodiments, an MPU 12 will be described as an example of the logical chips. Furthermore, in each of the following exemplary embodiments, the thickness direction (height direction) of the semiconductor module 1 is described as a thickness direction C. Furthermore, the side on which the substrate 15 is provided in the thickness direction C of the semiconductor module 1 is described as a lower side. The side on which the logical chip 12 is provided in the thickness direction C of the semiconductor module 1 is described as an upper side.

### FIRST EMBODIMENT

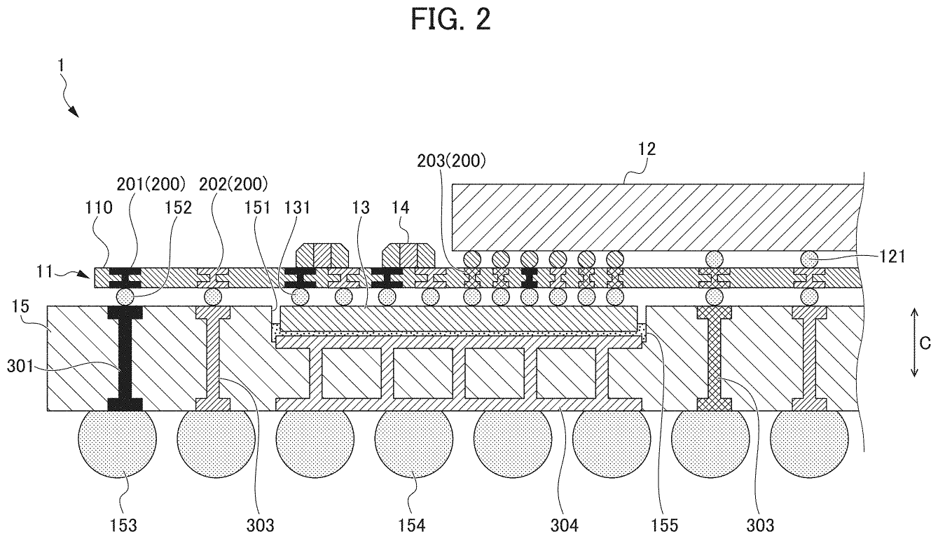

Next, a semiconductor module 1 according to the first embodiment and a manufacturing method thereof will be described with reference to FIGS. 1 to 9. The semiconductor module 1 according to the first embodiment, as shown in FIGS. 1 and 2, includes a film interposer 11, an MPU 12, a RAM unit 13, a capacitor 14, and a substrate 15. In the present embodiment, the semiconductor module 1 is disposed on one substrate 15 includes a single MPU 12, four RAM units 13, and a number of capacitors 14.

The film interposer 11 is a film having through electrodes therein in the thickness direction C. The film interposer 11 includes a base film 110 and vias 200.

The base film 110 is, for example, an insulating film such as polyimide (“Upilex” (Registered Trademark) available from Ube Industries, Ltd., having a thickness of 25 to 125 μm, an elastic modulus of 7.6 to 9.1 (25° C.), 3.7 to 3.8 (300° C.), and “Kapton” available from Teijin Limited, having a thickness of 12.5 to 125 μm, and an elastic modulus of 3.3 to 3.5. In the present embodiment, the base film 110 is used as a film cut into a rectangular shape.

The vias 200 are each a through electrode having conductivity. The vias 200 each penetrate from one surface to the other surface of the base film 110 in the thickness direction C. The vias 200 are used as, for example, a GND 201, a VDD 202 and a via 203 for signals.

The MPU 12 is a rectangular plate-shaped body in plan view. As shown in FIGS. 1 and 2, the MPU 12 is disposed on one surface of the film interposer 11. That is, the MPU 12 is disposed on one face of the base film 110. Furthermore, the MPU 12 is connected to the vias 200 using connection terminals (for example, solder balls, Cu pillars, solder bumps, plating, Au bumps, ACF, etc. In this embodiment, the MPU 12 is connected using the solder balls 121). The MPU 12 is electrically connected to, for example, the GND 201, the VDD 202 and the via 203 for signals using the solder balls 121.

As shown in FIG. 1, each of the RAM units 13 is composed of a RAM module having a rectangular shape in a plan view. The RAM unit 13 is disposed on the other direction face of the film interposer 11. The RAM unit 13 is connected to the vias 200 using the connection terminals (for example, solder balls, Cu pillars, solder bumps, plating, Au bumps, ACF, etc. In this embodiment, the RAM unit 13 is connected using the solder balls 131). The RAM unit 13 is electrically connected to, for example, the GND 201, the VDD 202, and the via 203 for signals using the solder balls 131. More specifically, the RAM unit 13 is electrically connected to the GND 201, the VDD 202, and the via 203 for signals which are the same as the GND 201, the VDD 202, and the via 203 for signals to which the MPU 12 is connected. That is, the RAM unit 13 is disposed so as to hold (sandwich) the film interposer 11 between the RAM unit 13 and the MPU 12.

The capacitor 14 is, for example, a bypass capacitor. The capacitor 14 is disposed on one face of the film interposer 11. The capacitor 14 is provided to reduce or prevent noise and power supply drop. The capacitor 14 is disposed, for example, at a position overlapping with another part of the RAM unit 13. Furthermore, the capacitor 14 is disposed to sandwich the film interposer 11 between the capacitor 14 and the RAM unit 13.

The substrate 15 is, for example, an organic substrate. In this embodiment, the substrate 15 has a rectangular shape in a plan view. The substrate 15 has a larger area than the MPU 12 in a plan view. The substrate 15 is disposed on the other face of the film interposer 11. The substrate 15 sandwiches the RAM unit 13 between the substrate 15 and the film interposer 11. In the present embodiment, the substrate 15 includes a GND 301, a VDD 302, and a via 303 for signals, which penetrate in the thickness direction C. Furthermore, in the present embodiment, the substrate 15 has a recess portion 151 at a position overlapping with the RAM unit 13 to include the RAM unit 13 therein. More specifically, the substrate 15 has a recess portion 151 having a size that allows the RAM unit 13 to be provided therein. Furthermore, the substrate 15 has a structure for dissipating heat generated from the RAM unit 13 at a position overlapping the recess portion 151, (for example, a structure obtained by combining a heat dissipating via and a heat dissipating pattern. In the present embodiment, such a structure is simplified and denoted as a dissipating via 304). Furthermore, the substrate 15 is disposed on the other face of the film interposer 11, and connected to the film interposer 11 using the connection terminals (for example, solder balls, Cu pillars, solder bumps, plating, Au bumps, ACF, etc. In the present embodiment, the substrate 15 is connected using the solder balls 152). Furthermore, the substrate 15 is connectable to another substrate using the solder balls 153 on the surface opposite to the surface facing the film interposer 11. Furthermore, the substrate 15 includes solder balls (in the present embodiment, these are denoted as heat dissipating balls 154) in contact with the heat dissipating via 304 on the surface opposite to the surface facing the film interposer 11, in order to dissipate heat from the heat dissipating via 304.

Next, the operation of the semiconductor module 1 will be described. The MPU 12 and RAM unit 13 generate heat by energizing. The heat generated in the MPU 12 and the RAM unit 13 is transferred to the solder balls. Furthermore, thermal warpage occurs in the MPU 12 and the RAM unit 13. The film interposer 11 absorbs stress due to thermal stress on the joint portions of the solder balls 121, 131, and 152, and the stress due to warpage of the MPU 12, the RAM unit 13, and the substrate 15.

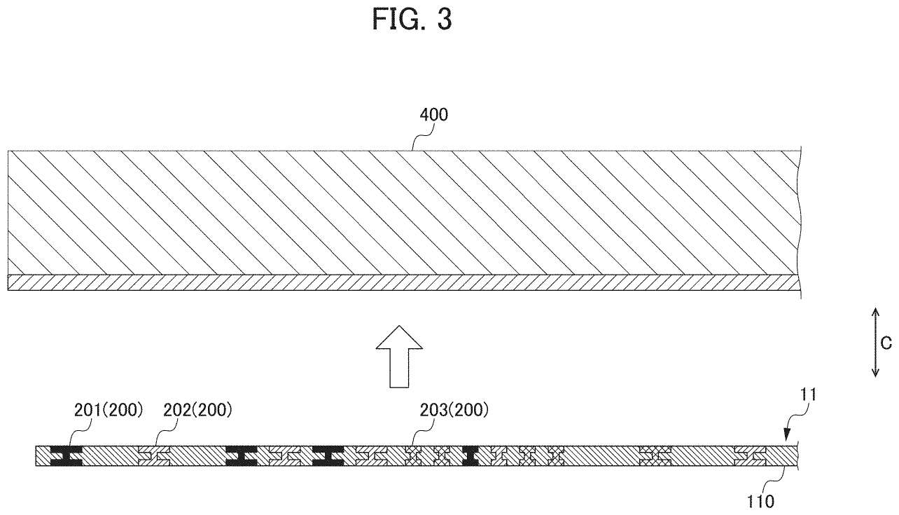

Next, a manufacturing method of the semiconductor module 1 will be described with reference to FIGS. 3 to 9. First, as shown in FIG. 3, through electrodes are formed in the film interposer 11. More specifically, the plurality of vias 200 are formed in the base film 110. Next, the film interposer 11 is attached to a plate-shaped support 400. More specifically, the film interposer 11 is attached to the support 400 with one surface thereof facing the support 400.

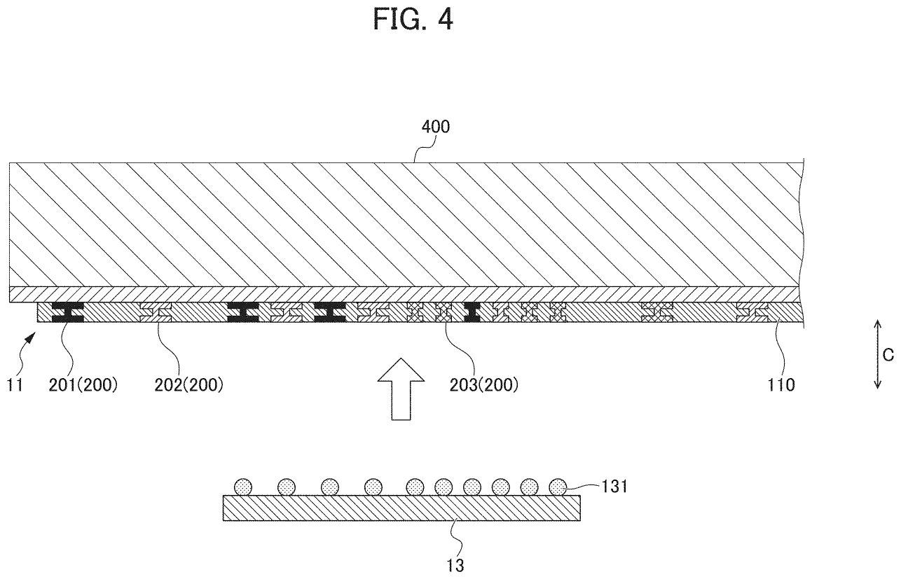

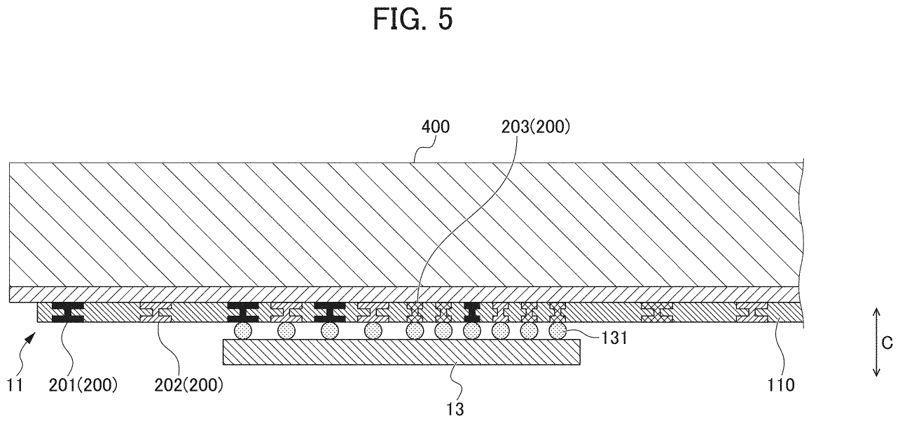

Next, as shown in FIG. 4, the RAM unit 13 is attached to the film interposer 11. Upon attaching to the film interposer 11, solder balls 131 are provided in advance in the RAM unit 13. As shown in FIG. 5, the RAM unit 13 is attached to the film interposer 11 so as to be aligned with the position of the solder balls 131 and the position of the vias 200.

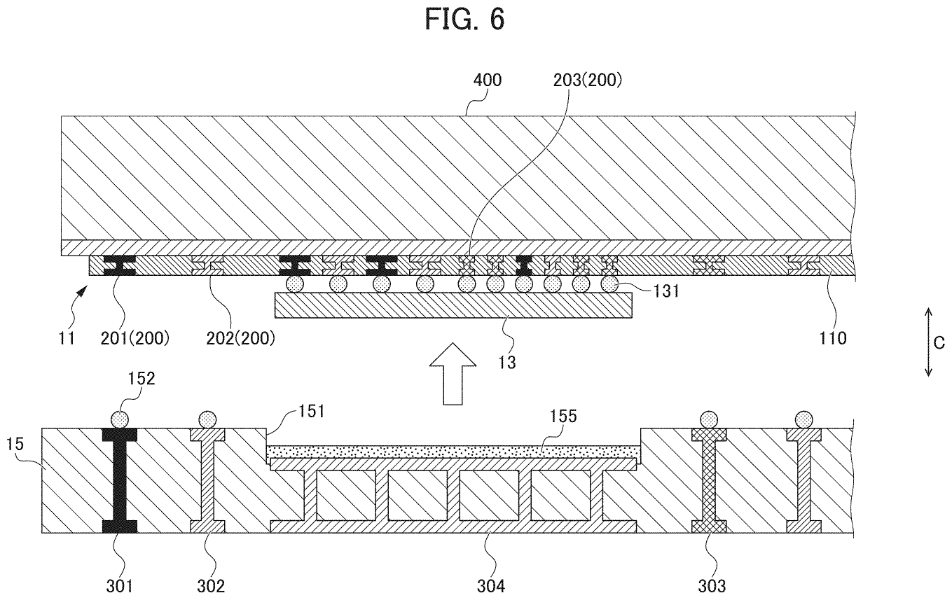

Next, as shown in FIG. 6, the substrate 15 is disposed on the other face of the film interposer 11. The RAM unit 13 is sandwiched between the substrate 15 and the film interposer 11. Upon placing the substrate 15, solder balls 152 are disposed in advance at the positions of the vias 200 on the substrate 15. Thereafter, the position of the recess portion 151 and the position of the RAM unit 13 are aligned, and the position of the solder balls 152 and the vias 200 are aligned such that the substrate 15 is disposed on the film interposer 11. Furthermore, the RAM unit 13 is fixed to the heat dissipating via 304 disposed at the position of the recess portion 151 by a die attach material 155 disposed at the position of the recess portion 151.

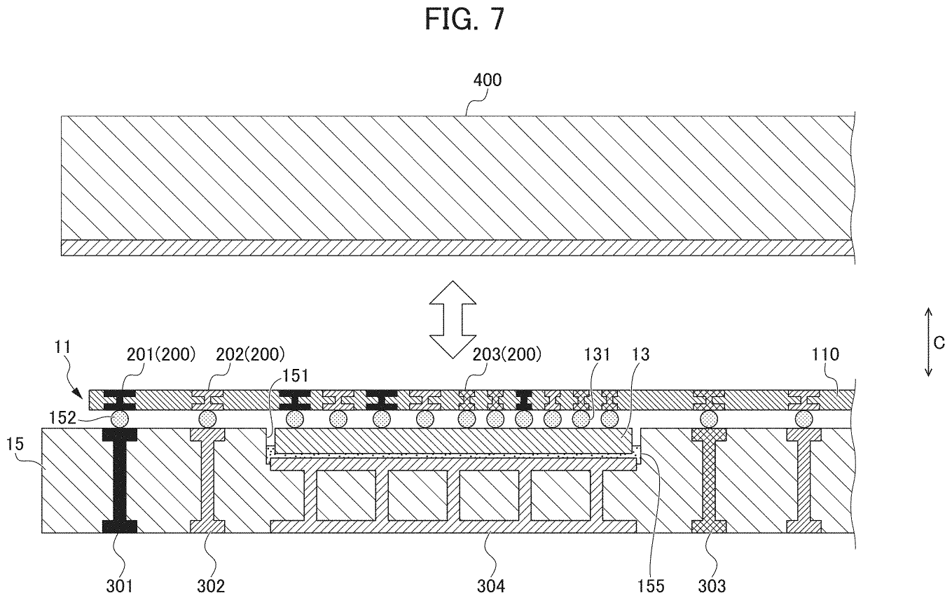

Next, as shown in FIG. 7, the support 400 is removed. That is, the support 400 is removed from one face of the film interposer 11.

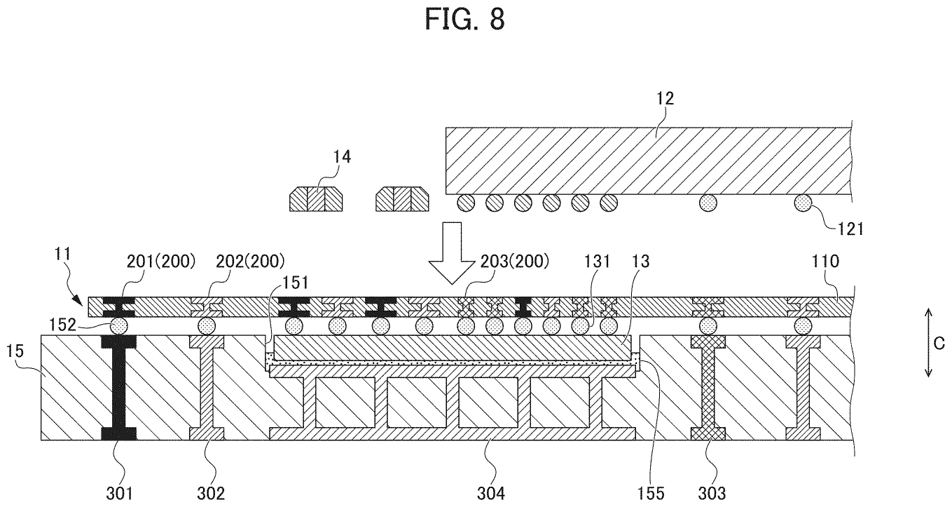

Next, as shown in FIG. 8, the MPU 12 is provided on one surface of the film interposer 11. Furthermore, the capacitor 14 is disposed on one surface of the film interposer 11. When the MPU 12 is provided, the solder balls 121 are provided on the MPU 12 in advance. The MPU 12 is disposed on one face of the film interposer 11 while the positions of the solder balls 121 and the vias 200 of the film interposer 11 are aligned. The capacitor 14 is attached by being aligned with the position of the via 200 on one surface of the film interposer 11.

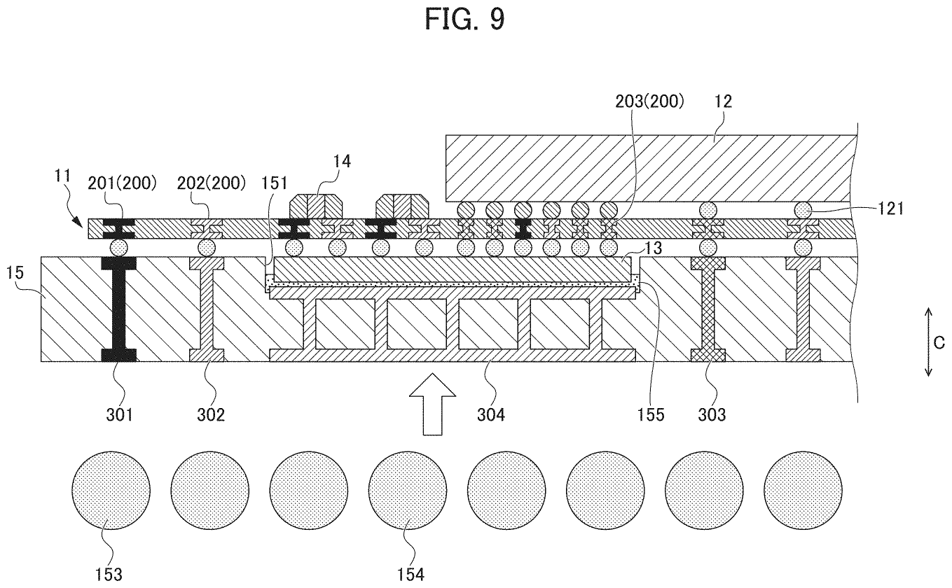

Then, as shown in FIG. 9, the solder balls 153 and the heat dissipating balls 154 are disposed on the other face of the substrate 15. More specifically, the solder balls 153 are provided so as to be aligned with the GND 301, the VDD 302, and the via 303 for signals of the substrate 15. The heat dissipating balls 154 are disposed so as to be aligned with the position of the heat dissipating via 304. Thus, the semiconductor module 1 is completed.

As described above, the semiconductor module 1 and the manufacturing method thereof according to the present exemplary embodiment have the following advantageous effects.

(1) The semiconductor module 1 includes: the film interposer 11 including the plurality of through electrodes penetrating in the thickness direction C; the MPU 12 provided on one face of the film interposer 11, and electrically connected to the plurality of through electrodes; and the RAM unit 13 serving as a RAM module provided on one other face of the film interposer 11, and electrically connected to the MPU 12 via the plurality of through electrodes. With such a configuration, it is possible to absorb thermal stress by the film interposer 11, and thus, it is possible to improve the reliability of the semiconductor module 1.
(2) At least a portion of the MPU 12 and at least a portion of the RAM unit 13 are provided to overlap each other with the film interposer 11 interposed therebetween. With such a configuration, the distance of the signal path between the MPU 12 and the RAM unit 13 can be shortened, such that the bandwidth of the signal between the MPU 12 and the RAM unit 13 can be widened.
(3) The semiconductor module 1 further includes the substrate 15 that is provided on the other face of the film interposer 11 and holds the RAM unit 13 between the substrate 15 and the other face of the film interposer 11. With such a configuration, the MPU 12 and the RAM unit 13 can be provided while the film interposer 11 is stabilized.
(4) The substrate 15 includes a recess portion at a position overlapping with the RAM unit 13 to include the RAM unit 13 therein. With such a configuration, it is possible to further reduce the thickness of the semiconductor module 1.
(5) The interposer includes the base film 110 and the plurality of vias 200 penetrating the base film 110. With such a configuration, the MPU 12 and the RAM unit 13 can be connected through the plurality of vias 200.

### SECOND EMBODIMENT

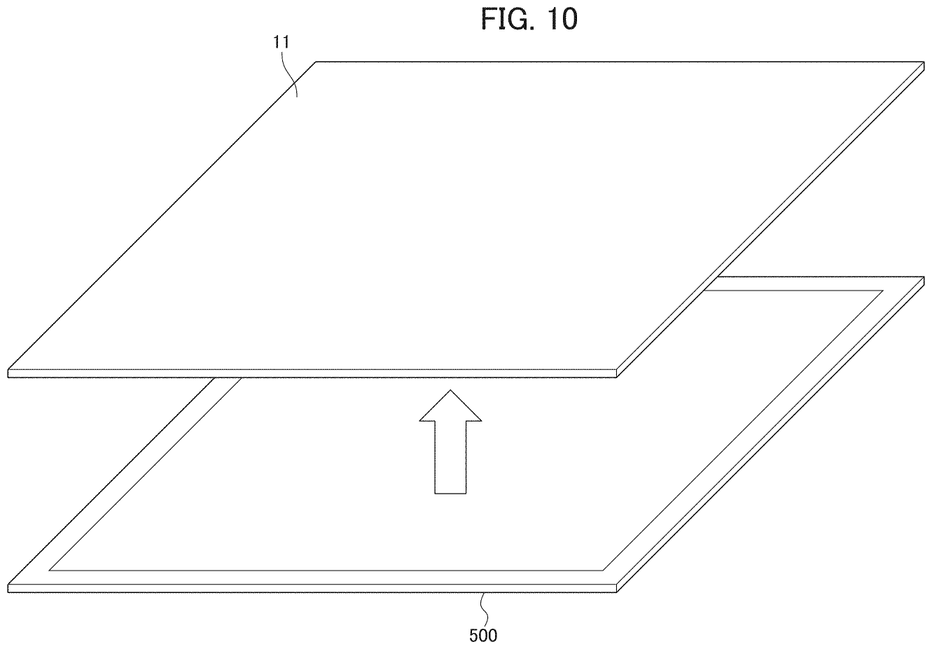

Next, a manufacturing method of the semiconductor module 1 according to a second exemplary embodiment of the present disclosure will be described with reference to FIGS. 10 to 12. In the description of the second embodiment, the same components as those of the above-described embodiment are denoted by the same reference numerals, and the descriptions thereof are omitted or simplified. The manufacturing method of the semiconductor module 1 according to the second exemplary embodiment differs from the first embodiment in that a plate-shaped frame 500 is used instead of the support 400. The manufacturing method of the semiconductor module 1 according to the second embodiment is a method of manufacturing a plurality of semiconductor modules 1 from one film interposer 11.

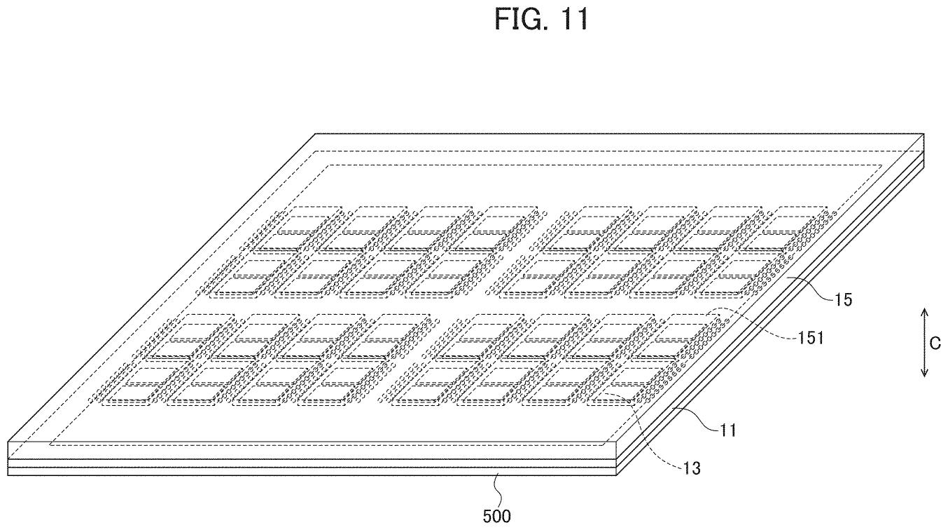

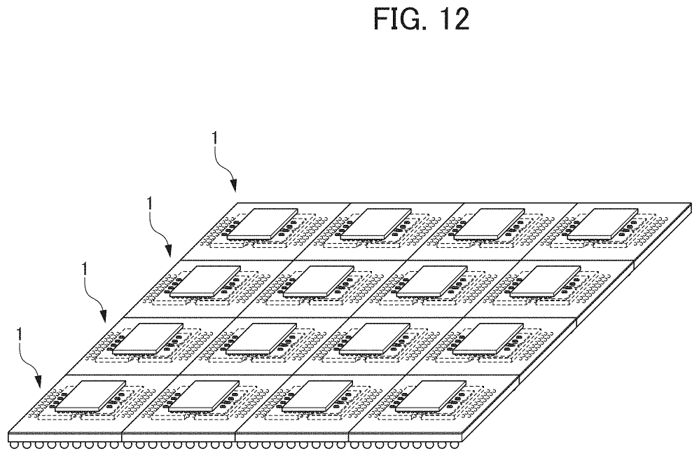

As shown in FIG. 10, an end on one face of the film interposer 11 faces and is placed on the plate-shaped frame 500. For example, the end on one face of the film interposer 11 faces and is placed on the frame 500 of 50 cm square. Next, as shown in FIG. 11, the plurality of RAM units 13 and the substrate 15 are provided on the other face of the film interposer 11. Next, as shown in FIG. 12, the frame 500 is removed, and a plurality of MPUs 12, a plurality of capacitors 14, a plurality of solder balls 153, and a heat dissipating ball 154 are provided. Then, by separating the semiconductor module 1 by dicing, individual semiconductor modules 1 are manufactured. It should be noted that the step of forming the plurality of vias 200 penetrating the base film 110 of the film interposer 11 may be performed before or after the end on the one face of the film interposer 11 is provided to face the plate-shaped frame 500.

As described above, the semiconductor module 1 according to the present embodiment has the following advantageous effects.

(6) The manufacturing method of the semiconductor module 1 includes the steps of: forming the plurality of through electrodes in the film interposer 11; providing the plate-shaped frame 500 so as to face the end of one face of the insulating film; providing the RAM unit 13 on one other face of the film interposer 11; providing the substrate 15 on the other face of the film interposer so as to hold the RAM unit 13 between the substrate 15 and the film interposer 11; removing the frame 500; and providing the MPU 12 on the one face of the film interposer 11. Thus, it is possible to efficiently manufacture a plurality of semiconductor modules 1 at the same time by using the frame 500.

### THIRD EMBODIMENT

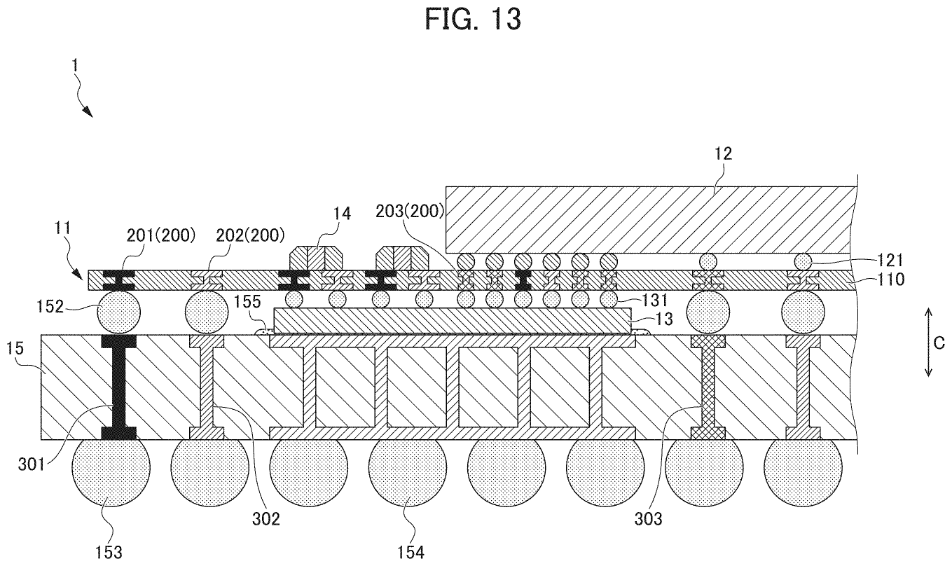

Next, a semiconductor module 1 according to a third exemplary embodiment of the present disclosure will be described with reference to FIG. 13. In the description of the third embodiment, the same components as those of the above-described embodiment are denoted by the same reference numerals, and the descriptions thereof are omitted or simplified. The semiconductor module 1 according to the third embodiment is different from the first embodiment in that the substrate 15 does not have the recess portion 151, as shown in FIG. 13. With such a configuration, it is not necessary to align the RAM unit 13 with the recess portion 151, and thus possible to eliminate the need for forming the recess portion 151. Therefore, it is possible to reduce the assembly cost of the semiconductor module 1.

### FOURTH EMBODIMENT

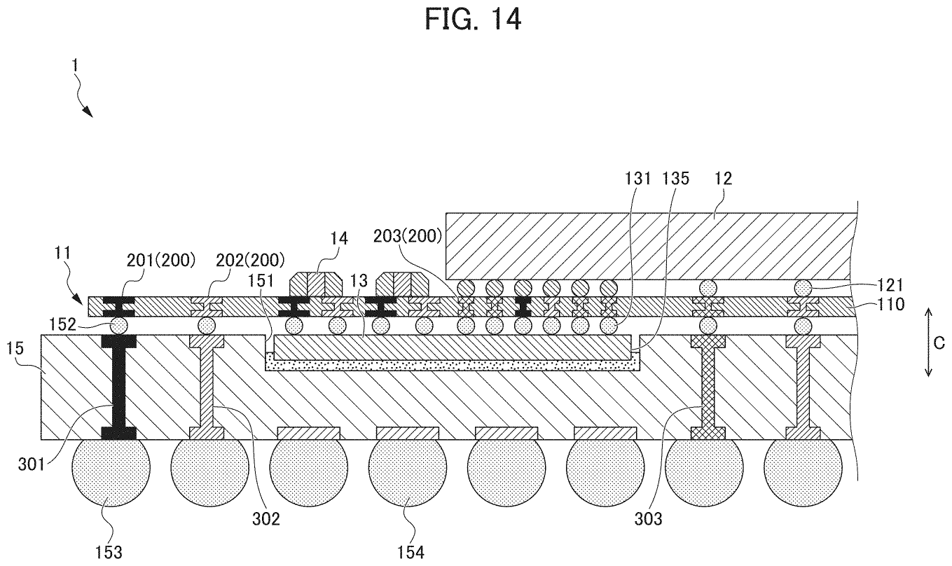

Next, a semiconductor module 1 according to a fourth exemplary embodiment of the present disclosure will be described with reference to FIG. 14. In the description of the fourth embodiment, the same components as those of the above-described embodiment are denoted by the same reference numerals, and the descriptions thereof are omitted or simplified. In the semiconductor module 1 according to the fourth embodiment, when the power consumption of the RAM unit 13 is small, as shown in FIG. 14, the heat dissipating via 304 is not necessarily formed on the substrate 15. Thus, it is possible to reduce the manufacturing cost of the semiconductor module 1.

### FIFTH EMBODIMENT

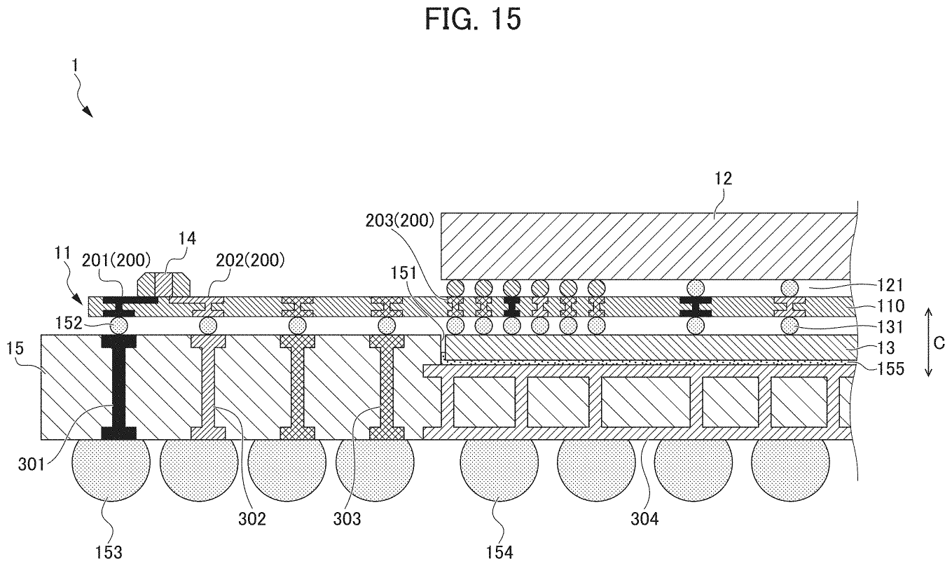

Next, a semiconductor module 1 according to a fifth exemplary embodiment of the present disclosure will be described with reference to FIG. 15. In the description of the fifth embodiment, the same components as those of the above-described embodiment are denoted by the same reference numerals, and the descriptions thereof are omitted or simplified. The semiconductor module 1 according to the fifth embodiment differs from the semiconductor module 1 according to the first embodiment in that, as shown in FIG. 15, the RAM unit 13 is disposed so as to overlap with the MPU 12. With such a configuration, since it is possible to draw power and signals in a wiring layer (not shown) of the film interposer 11, it is possible to improve the degrees of freedom in the arrangement position of the MPU 12 and the RAM unit 13.

### SIXTH EMBODIMENT

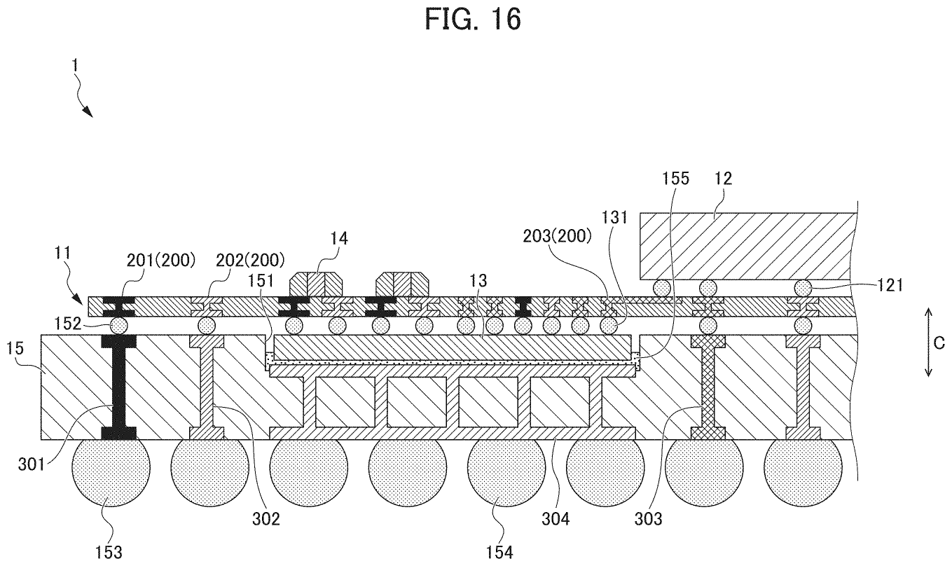

Next, a semiconductor module 1 according to a sixth exemplary embodiment of the present disclosure will be described with reference to FIG. 16. In the description of the sixth embodiment, the same components as those of the above-described embodiment are denoted by the same reference numerals, and the descriptions thereof are omitted or simplified. The semiconductor module 1 according to the sixth embodiment differs from the semiconductor module 1 according to the first embodiment in that, when the bandwidth of signals between the MPU 12 and the RAM unit 13 is not wide, the RAM unit 13 and the MPU 12 are arranged without overlapping each other as shown in FIG. 16. With such a configuration, the degrees of freedom in arrangement can be improved without any restriction from the mutual positional relationship of the RAM unit 13 and the MPU 12.

Although the preferred exemplary embodiments of the semiconductor module and the manufacturing method thereof of the present disclosure have been described above, the present disclosure is not limited to the above-described embodiments, and can be modified as appropriate.

For example, in the first and second embodiments, an example in which four RAM units 13 are provided for one MPU 12 is described; however, the present disclosure is not limited thereto. The number of the RAM units 13 may be changed as appropriate.

Furthermore, another connecting terminal such as Cu pillars, solder bumps, plating, Au bumps, ACFs (anisotropic conductive film) other than the solder balls 121, 131 and 152 as described in the above embodiments, and another connection method may be employed.

Furthermore, in the above-described embodiments, the arithmetic unit is not limited to the MPU 12, and may be widely applied to logical chips overall. In addition, memory is not limited to DRAM, and may be widely applied to RAM (Random Access Memory) including a non-volatile RAM (for example, MRAM, ReRAM, FeRAM, etc.).

### EXPLANATION OF REFERENCE NUMERALS

1 semiconductor module
11 film interposer
12 MPU (arithmetic unit, logic chip)
13 RAM unit
15 substrate
110 base film
151 recess portion
200 via
400 support
500 frame
C thickness direction

1. A semiconductor module comprising:
a film interposer including a plurality of through electrodes penetrating in a thickness direction;
a logical chip provided on one face of the film interposer, and electrically connected to the plurality of through electrodes; and
a RAM unit serving as a RAM module provided on one other face of the film interposer, and electrically connected to the logical chip via the plurality of through electrodes.

2. The semiconductor module according to claim 1, wherein at least a portion of the logical chip and at least a portion of the RAM unit are provided to overlap each other with the film interposer interposed therebetween.

3. The semiconductor module according to claim 1, further comprising a substrate that is provided on the other face of the film interposer and holds the RAM unit between the substrate and the other face of the film interposer.

4. The semiconductor module according to claim 3, wherein the substrate includes a recess portion at a position overlapping with the RAM unit to include the RAM unit therein.

5. The semiconductor module according to claim 1, wherein the film interposer includes
a base film, and
a plurality of vias penetrating the base film.

6. A manufacturing method of a semiconductor module, comprising the steps of:
forming a plurality of through electrodes in a film interposer;
providing a plate-shaped support so as to face one face of the film interposer;
providing a RAM unit on one other face of the film interposer;
providing a substrate on the other face of the film interposer so as to hold the RAM unit between the substrate and the film interposer;
removing the support; and
providing a logical chip on the one face of the film interposer.

7. A manufacturing method of a semiconductor module, comprising the steps of:
forming a plurality of through electrodes in a film interposer;
providing a plate-shaped frame so as to face an end of one face of the film interposer;
providing a RAM unit on one other face of the film interposer;
providing a substrate on the other face of the film interposer so as to hold the RAM unit between the substrate and the film interposer;
removing the frame; and
providing a logical chip on the one face of the film interposer.
